(19) United States
(12) Patent Application Publication
(10) Pub. No.: US 2026/0068571 A1
(43) Pub. Date: Mar. 5, 2026

(54) INTERCONNECT SCHEME FOR FULL HARD MASK REMOVAL

(71) Applicant: International Business Machines Corporation, Armonk, NY (US)

(72) Inventors: Xiaoming Yang, Clifton Park, NY (US); Lawrence Alfred Clevenger, Saratoga Springs, NY (US); Kai Zhao, Albany, NY (US)

(21) Appl. No.: 18/816,384

(22) Filed: Aug. 27, 2024

(51) Int. Cl. H01L 21/311; H01L 21/308; H01L 21/321; H01L 21/768; H01L 23/532

(52) U.S. Cl. CPC H01L 21/31144

(57) ABSTRACT

Methods for full hard mask removal and a semiconductor structure are presented. A semiconductor structure comprises a base layer of dielectric material; a body layer of a low-k dielectric material over the base layer; a hard mask over the body layer; and a plurality of trenches etched through the hard mask and the body layer and only partially etched into the base layer.

### BACKGROUND

The disclosure relates generally to the electrical, electronic, and computer arts, and more specifically, to fabricating semiconductor devices.

As feature size for semiconductor manufacturing continues to decrease, the importance of material selection of the device materials and processing materials increases. Materials for lithography, etching, pull, and other processes influence the quality and control over patterning.

Hard masks are used to transfer lithography patterns in processing. Hard mask materials are selected based on removal parameters, pattern control, and other aspects. Removal of some types of hard mask can present challenges based on material interactions. Additionally, residual hard masks can lead to delamination and other inconsistencies.

### SUMMARY

According to one illustrative embodiment, a method for forming interconnects over tungsten structures is presented. Trenches are etched into a semiconductor structure such that the trenches extend completely through a hard mask and a body layer of low-k dielectric material, and only partially into a base layer of dielectric material. The hard mask is removed while the base layer of dielectric material is only partially etched. The base layer of dielectric material is fully etched through to complete the trenches after the hard mask removal of the hard mask.

According to another illustrative embodiment, a method for fully removing hard masks for forming interconnects is presented. A base layer of dielectric material is partially etched. A hard mask removal of a titanium nitride hard mask over the base layer is performed while the base layer of dielectric material is partially etched. The dielectric material of the base layer is opened with a reactive ion etch after the hard mask removal of the titanium nitride hard mask.

According to yet another illustrative embodiment, a semiconductor structure is presented. The semiconductor structure comprises a base layer of dielectric material; a body layer of a low-k dielectric material over the base layer; a hard mask over the body layer; and a plurality of trenches etched through the hard mask and the body layer and only partially etched into the base layer.

In view of the foregoing, techniques of the present invention can provide substantial beneficial technical effects. For example, one or more embodiments provide a method of protecting tungsten during removal of titanium nitride hard masks. The one or more embodiments reduce delamination by completely removing hard masks. The one or more embodiments reduce voids in copper interconnects by reducing the aspect ratio.

Some embodiments may not have these potential advantages, and these potential advantages are not necessarily required of all embodiments. These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 is a flowchart illustrating steps of an interconnect process to fully remove a hard mask in accordance with an illustrative embodiment;

FIG. 2 is an illustration of a cross-sectional view of a structure produced by ILD dielectric RIE in accordance with an illustrative embodiment;

FIG. 3 is an illustration of a cross-sectional view of a structure produced by performing TiN HM removal in accordance with an illustrative embodiment;

FIG. 4 is an illustration of a cross-sectional view of a structure produced by performing OPL coating in accordance with an illustrative embodiment;

FIG. 5 is an illustration of a cross-sectional view of a structure produced by performing OPL overburden etch back in accordance with an illustrative embodiment;

FIG. 6 is an illustration of a cross-sectional view of a structure produced by performing SiON HM removal in accordance with an illustrative embodiment;

FIG. 7 is an illustration of a cross-sectional view of a structure produced by performing OPL ashing removal in accordance with an illustrative embodiment;

FIG. 8 is an illustration of a cross-sectional view of a structure after performing YUMA open RIE in accordance with an illustrative embodiment;

FIG. 9 is an illustration of a cross-sectional view of a structure after depositing copper barrier/seed in accordance with an illustrative embodiment;

FIG. 10 is an illustration of a cross-sectional view of a structure after performing copper plating in accordance with an illustrative embodiment;

FIG. 11 is an illustration of a cross-sectional view of a structure after performing copper CMP in accordance with an illustrative embodiment;

FIG. 12 is a flowchart of a method for forming interconnects over tungsten structures in accordance with an illustrative embodiment; and

FIG. 13 is a flowchart of a method for fully removing hard masks for forming interconnects in accordance with an illustrative embodiment.

### DETAILED DESCRIPTION

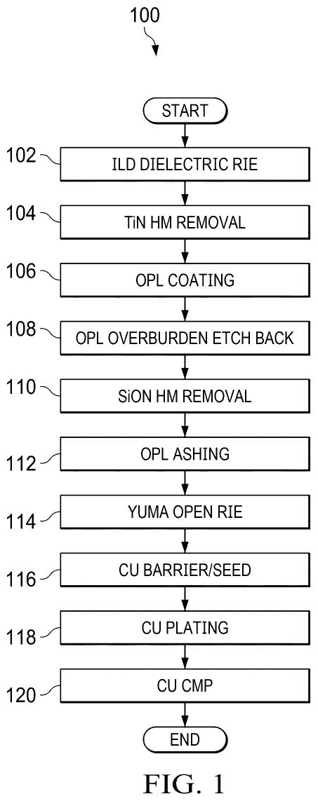

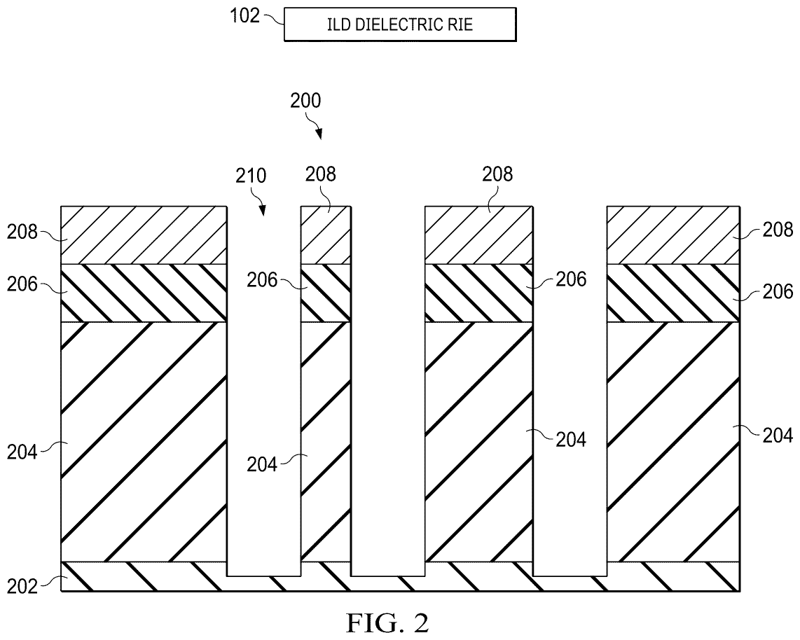

Turning now to FIG. 1, a flowchart illustrating steps of a full hard mask removal process to form interconnects is depicted in accordance with an illustrative embodiment. FIG. 1 depicts, in a flowchart, steps of the full hard mask removal process 100 to form interconnects, according to exemplary embodiments. FIG. 2 through FIG. 11 depict, in schematics, structures to be produced by steps of the process that is shown in FIG. 1, according to exemplary embodiments.

When tungsten (W) connects or vias are beneath an interconnect pattern, some hard masks cannot be removed with an etch. For example, titanium nitride (TiN) hard mask and SacN hard mask cannot be removed with T-Etch or EKC wet clean, because those clean solutions will damage tungsten. Some conventional methods to remove titanium nitride (TiN) hard mask and SacN hard mask include chemical mechanical planarization (CMP) can undesirably leave behind portions of the hard mask. Remaining hard mask can result in delamination and low yields.

The illustrative examples provide a new process integration scheme to remove titanium nitride (TiN) and silicon oxynitride (SiON) hard masks. By using the new method of hard mask removal, titanium nitride (TiN) and silicon oxynitride (SiON) hard masks can be used above tungsten layers. The use of titanium nitride (TiN) and silicon oxynitride (SiON) hard masks will reduce trench/via aspect ratio and provide for better metallization.

The illustrative examples provide a full hard mask removal with organic planarization layer (OPL) fill protection of underneath tungsten and low-K materials. The illustrative examples provide a full hard mask removal of TiN/SiON hard masks with OPL fill protection of the underneath tungsten and low-K materials. In some illustrative examples, full hard mask removal process 100 can be used for removal of LTO/SacN hard masks.

Full hard mask removal process 100 to form interconnects comprises step 102 of an ILD dielectric RIE. In step 102, the interlayer dielectric reactive ion etch (ILDRIE) is performed such that a base layer is only partially etched. The base layer comprises any desirable dielectric material. In some illustrative examples, the base layer is formed of Yuma. By only partially etching through the base layer, the base layer acts as protection for the lower layer metals. By only partially etching through the base layer, the base layer prevents the hard mask removal chemicals from damaging tungsten. With a partial dielectric etch, the bottom Yuma or Nblk is not fully opened, and atitanium nitride (TiN)hard mask can be removed by TEtch or EKC without damaging underneath tungsten.

At step 104, a titanium nitride (TiN) hard mask removal is performed. Next, at step 106, OPL coating is applied. The organic planarization layer (OPL) coating will provide additional protection against later hard mask removal steps. In step 108, an OPL overburden etch back is performed. After the OPL overburden etch back, the remaining silicon oxynitride (SiON) hard mask is exposed. After the OPL overburden etch back, OPL is present in the trenches and vias.

At step 110, the silicon oxynitride (SiON) hard mask is removed. The silicon oxynitride (SiON) hard mask is removed while the OPL is present in the trenches and vias. In some illustrative examples, a dry etch back will be employed to remove silicon oxynitride (SiON) hard mask with protection of OPL in the trench/via.

At step 112, OPL ashing is performed to remove the OPL. A low-K material in a body layer was protected with a thin remaining silicon oxynitride (SiON) hard mask film during OPL ashing and etch back.

At step 114, the base layer is opened at a final dielectric etch. In some illustrative examples, the final dielectric etch takes the form of Yuma open reactive ion etch (RIE). Metallization is performed after fully opening the base layer. The final dielectric etch removed the remaining silicon oxynitride (SiON) so that the metal does not delaminate during later processing. Although metallization is discussed below in terms of copper metallization, any desirable metal can be used.

Metallization begins with Cu seeding in step 116. Copper plating at step 118 completely fills the trenches and vias. Following plating, a copper CMP is performed at step 120 to remove excess copper outside of the trenches or vias.

Turning now to FIG. 2 through FIG. 11, structures to be produced by steps of full hard mask removal process 100 to form interconnects are depicted. In FIG. 2, an illustration of a cross-sectional view of a structure produced by ILD dielectric RIE is depicted in accordance with an illustrative embodiment.

In view 212, structure 200 is obtained from step 102 of ILD dielectric RIE. Structure 200 comprises base layer 202, body layer 204, first hard mask 206, and second hard mask 208. Each layer can comprise any desirable material and thickness of material based on creating a semiconductor structure.

Additional semiconductor structures are present beneath base layer 202. View 212 is a view of actively processed levels of a semiconductor stack. Structure 200 is a portion of a semiconductor stack for forming interconnects. Although not depicted in view 212, tungsten is present beneath base layer 202.

In some illustrative examples, base layer 202 can take the form of Yuma. In some illustrative examples, body layer 204 is formed of a low-k dielectric material. In some illustrative examples, body layer 204 can take the form of SiCONH. In some illustrative examples, body layer 204 can take the form of SiCNO. In some illustrative examples, first hard mask 206 can take the form of silicon oxynitride (SiON). In some illustrative examples, first hard mask 206 can take the form of silicon oxynitride (SiON) TBD nm thick. In some illustrative examples, second hard mask 208 can take the form of titanium nitride (TiN). In some illustrative examples, second hard mask 208 can take the form of titanium nitride (TiN) TBD nm thick.

In view 212, the ILD dielectric RIE has etched through body layer 204, first hard mask 206, and second hard mask 208. Trenches 210 have been etched through body layer 204, first hard mask 206, and second hard mask 208 and partially into base layer 202. The ILD dielectric RIE has only partially etched base layer 202. A portion of base layer 202 remains. By only partially etching base layer 202, tungsten beneath base layer 202 is protected from etching.

Trenches 210 are etched into a semiconductor structure 200 such that the trenches 210 extend completely through a hard mask, such as second hard mask 208, and body layer 204 of low-k dielectric material, and only partially into base layer 202 of dielectric material.

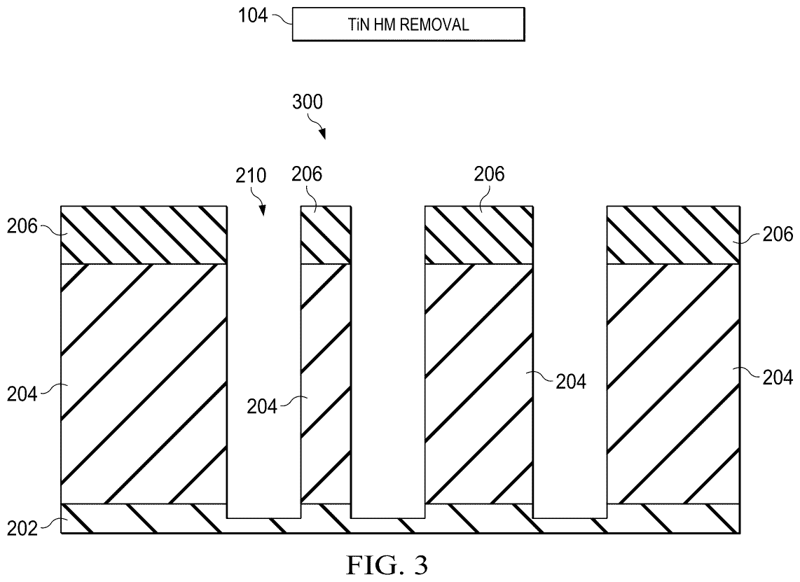

Turning now to FIG. 3, an illustration of a cross-sectional view of a structure produced by performing titanium nitride (TiN) HM removal is depicted in accordance with an illustrative embodiment. In view 300, step 104 for titanium nitride (TiN) hard mask removal has been performed. In view 300, second hard mask 208 has been removed. Base layer 202 protects materials beneath base layer 202 from etching of second hard mask 208.

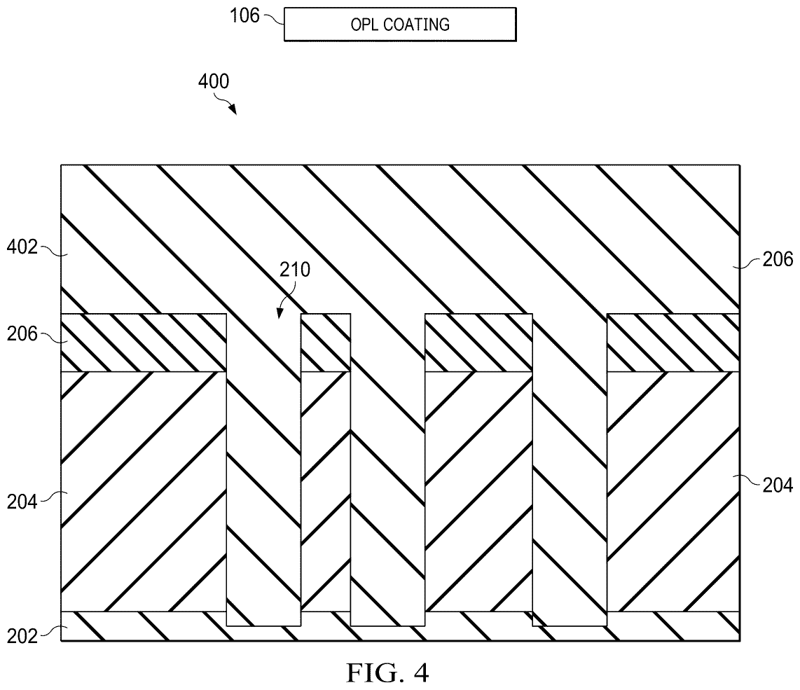

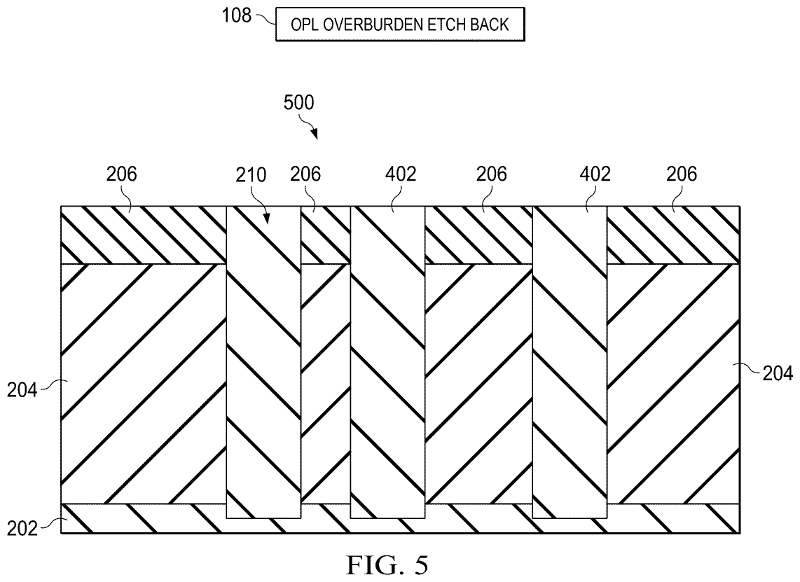

Turning now to FIG. 4, an illustration of a cross-sectional view of a structure produced by performing OPL coating is depicted in accordance with an illustrative embodiment. In view 400, step 106 of OPL coating deposition has been performed. Organic planarization layer (OPL) 402 has filled trenches 210 and covered first hard mask 206. In FIG. 5, an illustration of a cross-sectional view of a structure produced by performing OPL overburden etch back is depicted in accordance with an illustrative embodiment. Organic planarization layer (OPL) 402 outside of trenches 210 has been removed in view 500 by step 108.

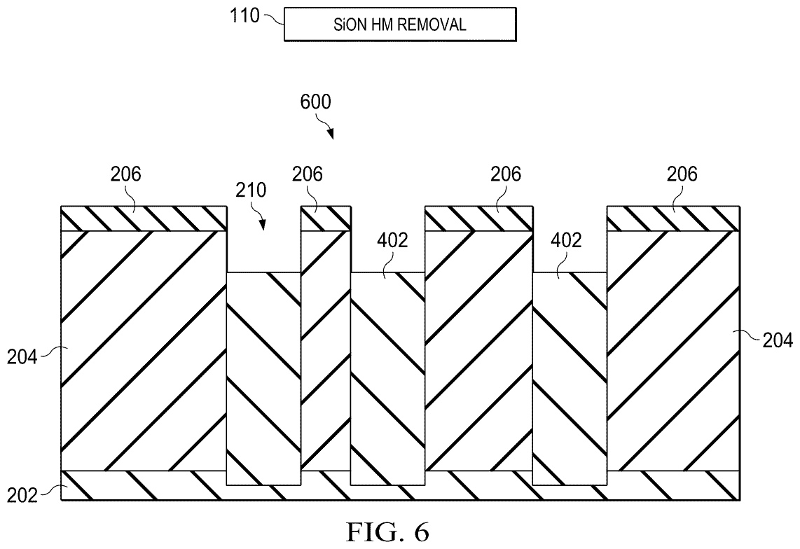

In FIG. 6, an illustration of a cross-sectional view of a structure produced by performing SiON HM removal is depicted in accordance with an illustrative embodiment. View 600 is a view following step 110. In step 110, first hard mask 206 removal is performed. In some illustrative examples, step 110 is a silicon oxynitride (SiON) hard mask removal. Organic planarization layer (OPL) 402 in trenches 210 protects lower materials from the silicon oxynitride (SiON) etch. A thin layer of first hard mask 206 remains to protect body layer 204 during OPL ashing depicted in step 112.

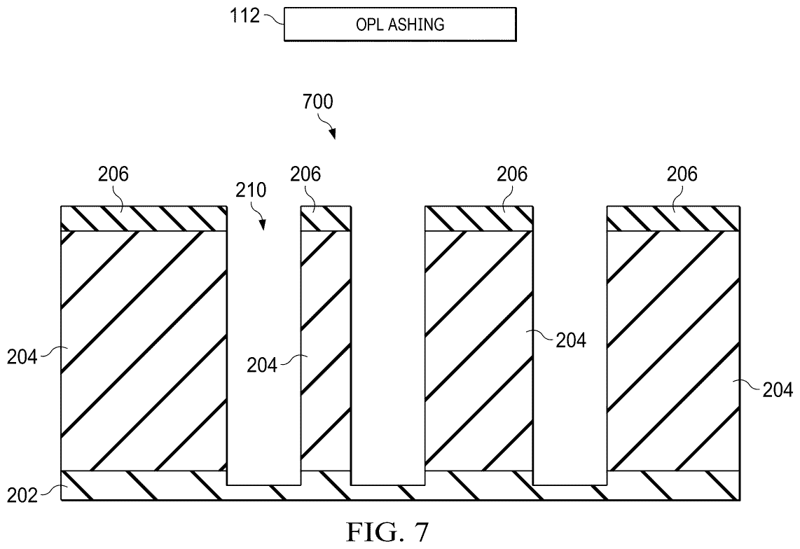

Turning now to FIG. 7, an illustration of a cross-sectional view of a structure produced by performing OPL ashing removal is depicted in accordance with an illustrative embodiment. View 700 is a view following step 112. During OPL ashing, OPL 402 is removed from trenches 210.

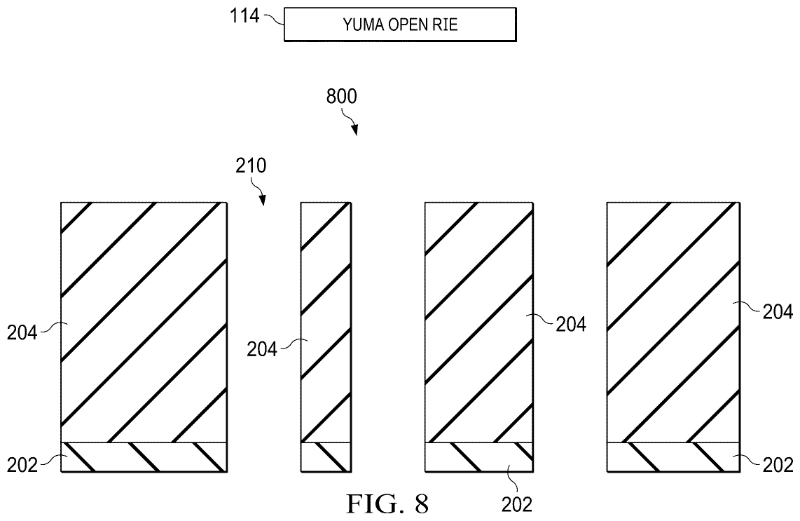

FIG. 8 is an illustration of a cross-sectional view of a structure after performing YUMA open RIE is depicted in accordance with an illustrative embodiment. In view 800, step 114 has been performed to completely extend trenches 210 through base layer 202. In view 800, a reactive ion etch (RIE) has been performed to open base layer 202. In some illustrative examples, base layer 202 takes the form of Yuma and step 114 is a Yuma open RIE. The reactive ion etch has removed the remaining portions of first hard mask 206. After step 114, all hard mask layers have been removed and metallization can be performed.

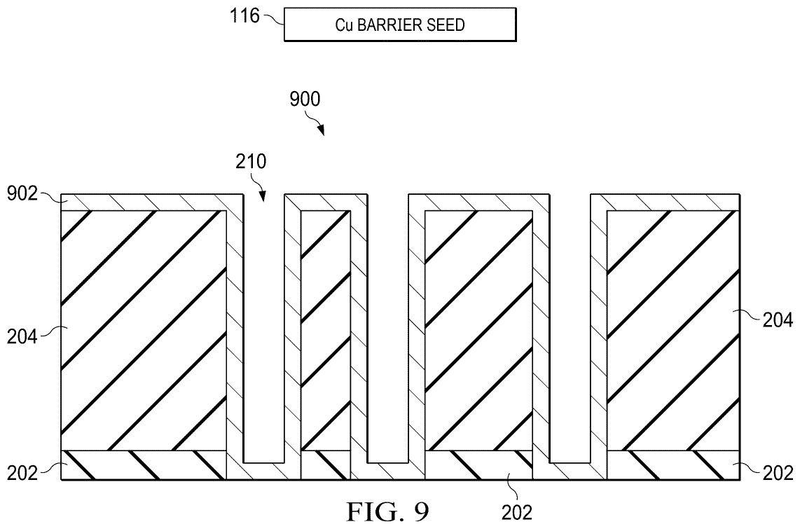

FIGS. 9-11 depict the method of metallization of trenches 210. FIG. 9 is an illustration of a cross-sectional view of a structure after depositing copper barrier/seed in accordance with an illustrative embodiment. In view 900, step 116 has been performed to deposit copper barrier seed layer 902. Copper barrier seed layer 902 extends across body layer 204, into trenches 210 and through base layer 202 to make contact with a layer below.

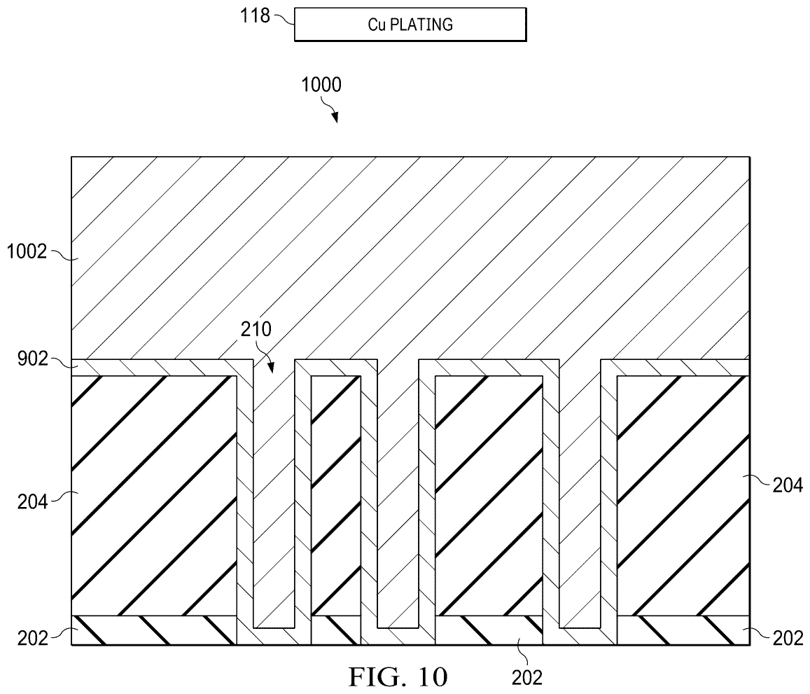

Turning now to FIG. 10, an illustration of a cross-sectional view of a structure after performing copper plating is depicted in accordance with an illustrative embodiment. In view 1000, step 118 has been performed to fill trenches 210 with copper 1002. Step 118 takes the form of copper plating. Excess coper is present outside of trenches 210 and extending over body layer 204. Chemical mechanical planarization (CMP) is performed to remove the excess copper.

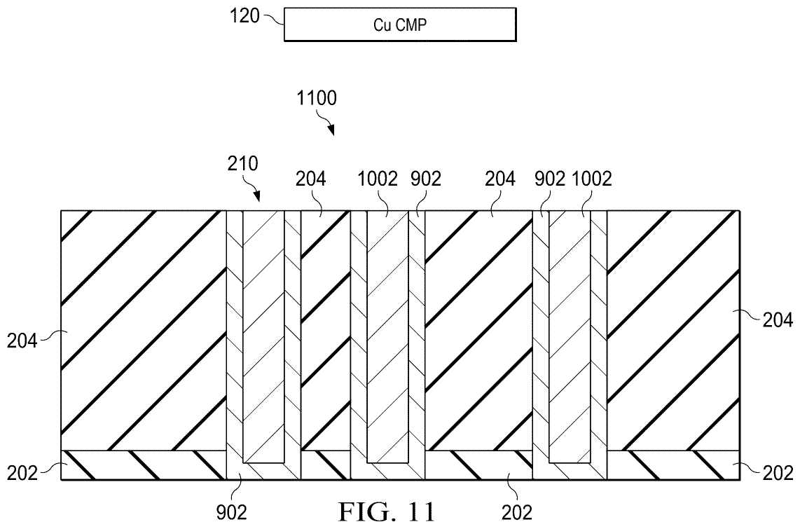

In FIG. 11, an illustration of a cross-sectional view of a structure after performing copper CMP is depicted in accordance with an illustrative embodiment. In view 1100, copper CMP has been performed in step 120 to remove excess copper. In view 1100, trenches 210 have been filled with copper 1002 to form interconnects.

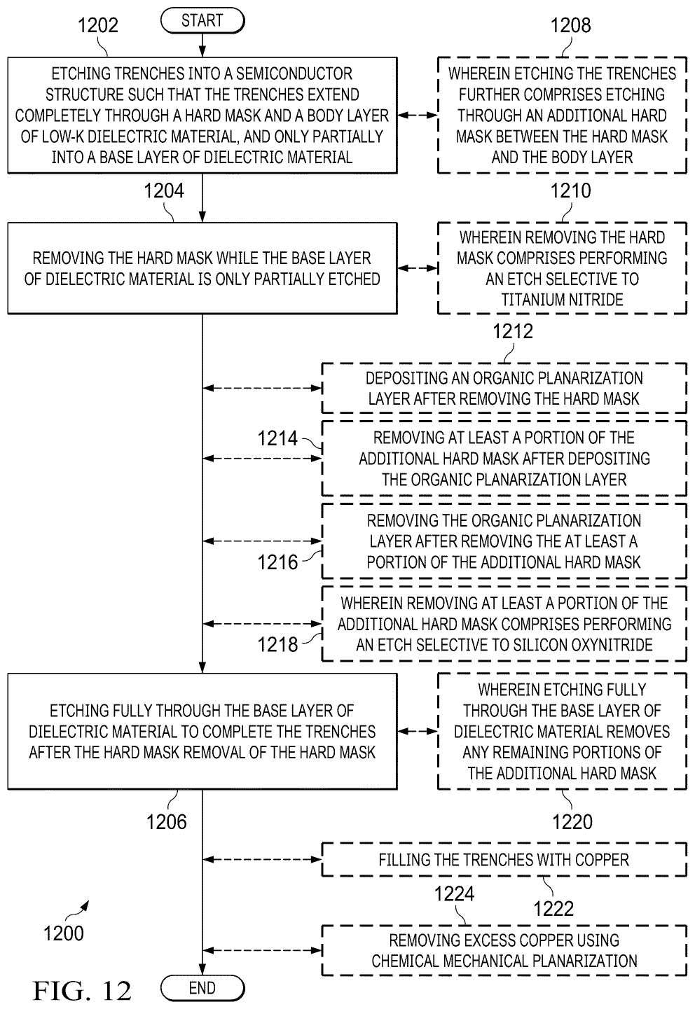

Turning now to FIG. 12, a flowchart of a method for forming interconnects over tungsten structures is depicted in accordance with an illustrative embodiment. Structures in FIGS. 2-11 are schematic representations of a semiconductor structure during portions of method 1200.

Method 1200 etches trenches into a semiconductor structure such that the trenches extend completely through a hard mask and a body layer of low-k dielectric material, and only partially into a base layer of dielectric material (operation 1202). In one illustrative example, in view 212 of FIG. 2, trenches 210 are etched into a semiconductor structure 200 such that the trenches 210 extend completely through a hard mask, such as second hard mask 208, and body layer 204 of low-k dielectric material, and only partially into base layer 202 of dielectric material.

Method 1200 removes the hard mask while the base layer of dielectric material is only partially etched (operation 1204). In one illustrative example, in view 300 of FIG. 3, second hard mask 208 is removed while base layer 202 of dielectric material is only partially etched.

Method 1200 etches fully through the base layer of dielectric material to complete the trenches after the hard mask removal of the hard mask (operation 1206). In one illustrative example, in view 800 of FIG. 8, base layer 202 of dielectric material is etched fully through to complete trenches 210 after the hard mask removal of second hard mask 208. Afterwards, method 1200 terminates.

In some illustrative examples, etching the trenches further comprises etching through an additional hard mask between the hard mask and the body layer (operation 1208). In one illustrative example, etching trenches 210 in view 212 in FIG. 2 further comprises etching through an additional hard mask between the hard mask and body layer 204, first hard mask 206.

In some illustrative examples, removing the hard mask comprises performing an etch selective to titanium nitride (operation 1210). In some of these illustrative examples, the base layer protects underlying tungsten structures during the etch selective to titanium nitride.

In some illustrative examples, method 1200 deposits an organic planarization layer after removing the hard mask (operation 1212). One illustrative example is depicted in view 400 in which organic planarization layer (OPL) 402 is deposited after removing second hard mask 208.

In some illustrative examples, method 1200 removes at least a portion of the additional hard mask after depositing the organic planarization layer (operation 1214). One illustrative example is depicted in view 600 where at least a portion of the additional hard mask, first hard mask 206, is removed after depositing organic planarization layer (OPL) 402.

In some illustrative examples, method 1200 removes the organic planarization layer after removing the at least a portion of the additional hard mask (operation 1216). One illustrative example is depicted in view 700 where the organic planarization layer 402 is removed after removing the at least a portion of the additional hard mask.

In some illustrative examples, removing at least a portion of the additional hard mask comprises performing an etch selective to silicon oxynitride (operation 1218).

In some illustrative examples, etching fully through the base layer of dielectric material removes any remaining portions of the additional hard mask (operation 1220). In some illustrative examples, and as depicted in view 800, etching fully through base layer 202 of dielectric material removes any remaining portions of the additional hard mask, first hard mask 206.

In some illustrative examples, method 1200 fills the trenches with copper (operation 1222). One illustrative example is depicted in view 900 and view 1000 of FIGS. 9 and 10, where trenches 210 are filled with copper. In some illustrative examples, method 1200 removes excess copper using chemical mechanical planarization (operation 1224). One illustrative example is depicted in view 1100 in which excess copper is removed using chemical mechanical planarization.

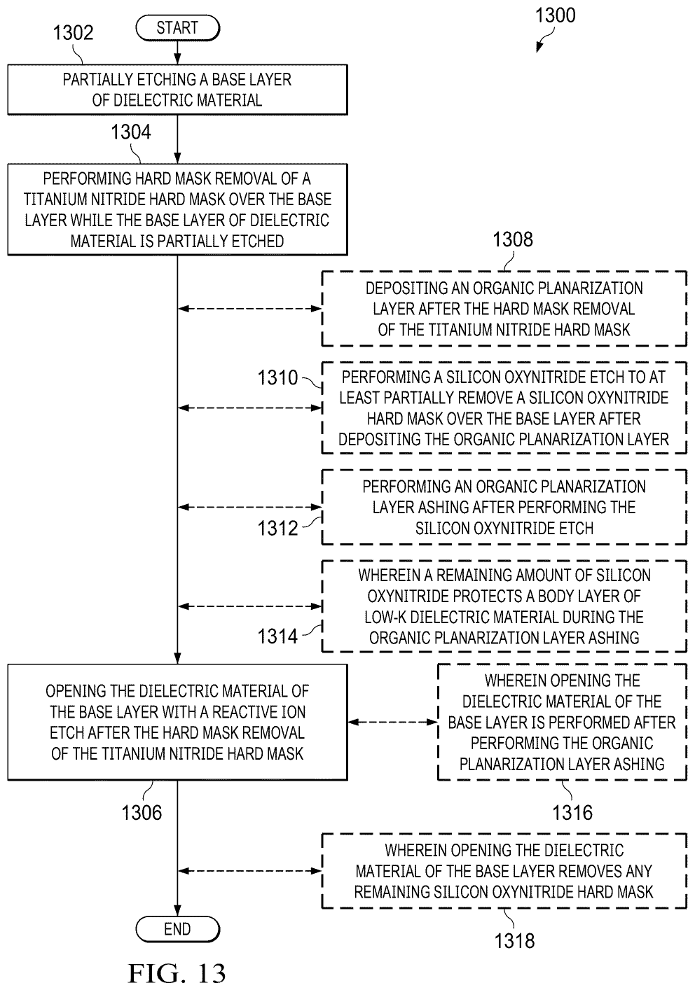

Turning now to FIG. 13, a flowchart of a method for fully removing hard masks for forming interconnects is depicted in accordance with an illustrative embodiment. Structures in FIGS. 2-11 are schematic representations of a semiconductor structure during portions of method 1300.

Method 1300 partially etches a base layer of dielectric material (operation 1302). In view 212, base layer 202 of dielectric material is partially etched. In some illustrative examples, the base layer of dielectric material protects underlying tungsten structures during the hard mask removal of the titanium nitride hard mask.

Method 1300 performs hard mask removal of a titanium nitride hard mask over the base layer while the base layer of dielectric material is partially etched (operation 1304). In view 300, hard mask removal of a titanium nitride hard mask, second hard mask 208, over the base layer 202 is performed while base layer 202 of dielectric material is partially etched.

Method 1300 opens the dielectric material of the base layer with a reactive ion etch after the hard mask removal of the titanium nitride hard mask (operation 1306). In view 800, dielectric material of base layer 202 is opened with a reactive ion etch after the hard mask removal of the titanium nitride hard mask. Afterwards, method 1300 terminates.

In some illustrative examples, method 1300 deposits an organic planarization layer after the hard mask removal of the titanium nitride hard mask (operation 1308). One illustrative example is depicted in view 400 in which organic planarization layer 402 is deposited after the hard mask removal of the titanium nitride hard mask, second hard mask 208.

In some illustrative examples, method 1300 performs a silicon oxynitride etch to at least partially remove a silicon oxynitride hard mask over the base layer after depositing the organic planarization layer (operation 1310). One illustrative example is depicted in view 600 where a silicon oxynitride etch is performed to at least partially remove a silicon oxynitride hard mask, first hard mask 206, over base layer 202 after depositing organic planarization layer 402.

In some illustrative examples, method 1300 performs an organic planarization layer ashing after performing the silicon oxynitride etch (operation 1312). One illustrative example is depicted in view 700. In some illustrative examples, a remaining amount of silicon oxynitride protects a body layer of low-k dielectric material during the organic planarization layer ashing (operation 1314).

In some illustrative examples, opening the dielectric material of the base layer is performed after performing the organic planarization layer ashing (operation 1316). In some illustrative examples, opening the dielectric material of the base layer removes any remaining silicon oxynitride hard mask (operation 1318). In some illustrative examples and as depicted in view 800, opening the dielectric material of base layer 202 removes any remaining silicon oxynitride hard mask, first hard mask 206.

With each of full hard mask removal process 100, method 1200, and method 1300, copper voids can be reduced due to the reduced aspect ratio of the hard masks utilized. More specifically, titanium nitride (TiN) and silicon oxynitride (SiON) hard masks allow for the trench/via AR (aspect-ratio) to be significantly reduced, which benefits Cu barrier/seed gap-fill to eliminate metal voids and improve yield and reliability.

Each of full hard mask removal process 100, method 1200, and method 1300 allow for the use of titanium nitride (TiN) and silicon oxynitride (SiON) hard masks without deterioration of underlying Tungsten. The incomplete etch of the base layer Yuma protects underlying Tungsten from the etches.

Each of full hard mask removal process 100, method 1200, and method 1300 reduce delamination by completing removing the hard masks. The hard masks are removed through a series of etches while the underlying structures are protected by the Yuma base layer and OPL.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

The flowcharts in the different depicted embodiments illustrate the operation of some possible implementations of methods in an illustrative embodiment. In this regard, each block in the flowcharts may represent at least one of a module, a segment, a function, or a portion of an operation or step. Other blocks may be added in addition to the illustrated blocks in a flowchart or block diagram. Some blocks may be optional. For example, operation 1208 through operation 1224 may be optional. As another example, operation 1308 through operation 1318 may be optional.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method for forming interconnects over tungsten structures, the method comprising:
etching trenches into a semiconductor structure such that the trenches extend completely through a hard mask and a body layer of low-k dielectric material, and only partially into a base layer of dielectric material;
removing the hard mask while the base layer of dielectric material is only partially etched; and
etching fully through the base layer of dielectric material to complete the trenches after the hard mask removal of the hard mask.

2. The method of claim 1, wherein removing the hard mask comprises performing an etch selective to titanium nitride.

3. The method of claim 1, wherein the base layer protects underlying tungsten structures during the etch selective to titanium nitride.

4. The method of claim 1, wherein etching the trenches further comprises etching through an additional hard mask between the hard mask and the body layer, the method further comprising:
depositing an organic planarization layer after removing the hard mask; and
removing at least a portion of the additional hard mask after depositing the organic planarization layer; and
removing the organic planarization layer after removing the at least a portion of the additional hard mask.

5. The method of claim 4, wherein removing at least a portion of the additional hard mask comprises performing an etch selective to silicon oxynitride.

6. The method of claim 4, wherein etching fully through the base layer of dielectric material removes any remaining portions of the additional hard mask.

7. The method of claim 1 further comprising:
filling the trenches with copper; and
removing excess copper using chemical mechanical planarization.

8. A method for fully removing hard masks for forming interconnects, the method comprising:
partially etching a base layer of dielectric material;
performing hard mask removal of a titanium nitride hard mask over the base layer while the base layer of dielectric material is partially etched; and
opening the dielectric material of the base layer with a reactive ion etch after the hard mask removal of the titanium nitride hard mask.

9. The method of claim 8 further comprising:
depositing an organic planarization layer after the hard mask removal of the titanium nitride hard mask; and
performing a silicon oxynitride etch to at least partially remove a silicon oxynitride hard mask over the base layer after depositing the organic planarization layer.

10. The method of claim 9 further comprising:
performing an organic planarization layer ashing after performing the silicon oxynitride etch.

11. The method of claim 10, wherein a remaining amount of silicon oxynitride protects a body layer of low-k dielectric material during the organic planarization layer ashing.

12. The method of claim 10, wherein opening the dielectric material of the base layer is performed after performing the organic planarization layer ashing.

13. The method of claim 12, wherein opening the dielectric material of the base layer removes any remaining silicon oxynitride hard mask.

14. The method of claim 12, wherein the base layer of dielectric material protects underlying tungsten structures during the hard mask removal of the titanium nitride hard mask.

15. A semiconductor structure comprising:
a base layer of dielectric material;
a body layer of a low-k dielectric material over the base layer;
a hard mask over the body layer; and
a plurality of trenches etched through the hard mask and the body layer and only partially etched into the base layer.

16. The semiconductor structure of claim 15, wherein the hard mask comprises silicon oxynitride.

17. The semiconductor structure of claim 15 further comprising a second hard mask over the hard mask, wherein the plurality of trenches is etched through the second hard mask.

18. The semiconductor structure of claim 17, wherein the second hard mask comprises titanium nitride.

19. The semiconductor structure of claim 15, wherein the base layer comprises Yuma.

20. The semiconductor structure of claim 15, wherein the base layer of dielectric material is positioned above a tungsten structure.
